(19) United States
(12) Patent Application Publication
(10) Pub. No.: US 2006/0083993 A1
(43) Pub. Date: Apr. 20, 2006

(54) Process for the production of photomasks for structuring semiconductor substrates by optical lithography

(76) Inventors: Oliver Kirch, Erlangen (DE); Michael Sebald, Weisendorf (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 10/516,262

(22) PCT Filed: Apr. 30, 2003
(86) PCT No.: PCT/DE03/01394

§ 371 Date: Aug. 16, 2005

(30) Foreign Application Priority Data
May 29, 2002 (DE) 102 23 997.5

(51) Int. Cl. G03C 1/494; G03C 5/00; G03C 1/492; G03C 1/76; G03F 1/00

(52) U.S. Cl. 430/5; 430/270.1; 430/322; 430/323; 430/324

(57) ABSTRACT

The invention relates to a process for the production of photomasks for structuring semiconductors. A resist that contains a polymer having silicon-containing groups is used. During the structuring in an oxygen-containing plasma, the silicon atoms are converted into silica which protects absorber parts arranged under the silica from removal by the plasma.

The invention relates to a process for the production of photomasks for optical lithography. The photomasks are suitable for structuring semiconductor substrates, e.g. silicon wafers.

In the production of microchips, lithographic processes are used for structuring semiconductor substrates. Semiconductor substrates used are in general silicon wafers into which structures or components may also have already been introduced. First, a thin layer of a photoresist is applied to the semiconductor substrate, the chemical or physical properties of which photoresist can be changed by exposure to light. The photoresist is exposed to light, in general monochromatic light, in particular laser light, being used. A photomask which contains all information on the structure to be formed is introduced into the beam path between radiation source and photoresist. In the simplest case, the structure contained in the photomask corresponds to the approximately 5-fold magnified image of the structure to be produced on the semiconductor substrate. This structure is projected with the aid of a corresponding optical system onto the photoresist so that the photoresist is exposed section by section and chemical modification of the photoresist is effected, for example in the exposed sections. The exposed photoresist is developed with a developer, selectively for example only the exposed parts being removed. The remaining unexposed resist sections then serve as a mask for processing the semiconductor substrate. The structure determined by the resist mask can be transferred to the semiconductor substrate, for example, by dry etching with an etching plasma in order, for example, to produce trenches for trench capacitors. However, the resist structures can also be filled with a further material, for example polysilicon, in order to produce conductor tracks.

The photomask arranged in the beam path is produced by writing by means of an electron beam on a substrate coated with a photoresist. For this purpose, a layer of an absorber material is first applied to a transparent substrate, generally a quartz glass. In the case of COG masks (COG=“chrome on glass”) as the simplest example of a photomask, the absorber material consists of a thin chromium layer. In order to be able to structure the layer of the absorber material, i.e. for example the chromium layer, a layer of a photoresist which can be changed in its properties by irradiation is first applied to the chromium layer. At present, a layer of polymethyl methacrylate (PMMA) is usually used as a photoresist layer. This photoresist layer is then written on with the aid of a mask writer using an electron beam. Those parts in which the chromium layer is to be removed in a subsequent operation in order to obtain transparent sections of the mask are exposed to the electron beam. The polymethyl methacrylate is cleaved into smaller fragments by the energy of the electron beam. The different solubilities of PMMA and of the fragments formed from the PMMA by exposure in a solvent are utilized for developing the exposed photoresist. For this purpose, a developer, generally an organic solvent, which selectively dissolves only the fragments formed from the PMMA in the exposed parts, while the PMMA remains unchanged on the chromium layer in the unexposed parts, is added to the exposed photoresist. The structure formed from the photoresist is now transferred with the aid of an etching plasma into the chromium layer arranged underneath. For this purpose, an oxygen/chlorine gas mixture is used in order to form volatile chromium compounds. In the bare sections not covered by the mask, the chromium layer is removed and the transparent quartz substrate arranged under the chromium layer is bared.

However, the currently used photoresists are very strongly attacked by the oxygen component contained in the etching plasma, so that the photoresist is removed at the edges of the structured produced from the photoresist, and the chromium layer arranged underneath is no longer protected. This results in a considerable lateral structure loss at the chromium edges. Conventional metrology losses in chromium are about 50 nm per edge. After the etching process, the absorber lines produced from the chromium layer may therefore be up to 100 nm narrower than the width defined by the photoresist. This structure loss was hitherto already taken into account in the mask layout and a corresponding structure reserve was provided. The absorber lines to be produced from the chromium layer were thus simply broadened in the mask layout. For structure dimensions of more than 0.25 μm, as occur in the case of the photomasks currently used for the production of microchips, this furthermore presents no difficulties at all. With decreasing dimensions of the structures to be produced in the semiconductor substrate, however, the size of the absorber structures contained in the photomask also decreases. Furthermore, diffraction and interference effects which adversely affect the resolution of the photomask occur in the imaging of very small structures. In order to improve the resolution, nonimaging elements are therefore added to the structural elements in the photomask which are to be imaged, in order thus to achieve a steeper transition between exposed and unexposed sections on the photoresist in the structuring of semiconductor substrates. The nonimaging structures of the photomask have a line width which is below the resolution of the imaging apparatus. The resolution is determined in particular by the wavelength of the radiation used for exposure of the photoresist. This method for improving the imaging by introducing nonimaging structural elements into the photomask is also referred to as OPC (optical proximity correction). By means of this, the structure reproduced and the structure of the photomask are no longer similar. The photomask thus also contains auxiliary structures in addition to the structures to be reproduced. In the production of the photomask, a substantially larger number of structural elements than corresponds to the reproduced structure must therefore be produced. If the reduction in the dimensions of the photomask which is due to the reduction in the size of the structures to be produced in the semiconductor substrate is taken into account, it is directly evident that the latitude available for a structure reserve in the production of the photomask decreases continuously or is no longer present. The nonimaging auxiliary structures of the photomask will in the near future reach dimensions down to 100 nm or less and will have to be arranged a defined distance away from the main structures of the photomask. In the case of these very fine structural dimensions, a prior correction of the mask layout, i.e. a structure reserve, is no longer possible. In the case for example of a required distance of 100 nm and a simultaneous structure reserve of in each case 50 nm per edge, the structures would collapse into a single line in the layout itself.

A further problem in the production of photomasks is that the structured photoresist is removed to a particularly great extent at the edges by the plasma and the edges are therefore rounded. Initially rectangular resist structures are therefore not exactly transferred into the absorber layer. There is at present no photoresist with which structures having a line spacing of 50 nm can be produced in the chromium mask.

It is therefore an object of the invention to provide a process for the production of photomasks for optical lithography, by means of which structures having a very small line spacing can also be produced in an absorber layer.

The object is achieved by a process for the production of photomasks for optical lithography,

a transparent substrate being provided,

a first layer of an absorber material being deposited on the transparent substrate,

a layer of a resist for electron beam lithography being applied to the first layer, which resist at least comprises:

a film-forming polymer, which comprises silicon atoms, and

a solvent,

and solvent contained in the resist being evaporated to give a second layer which contains the film-forming polymer,

the second layer being written on by means of a focused electron beam so that an image which comprises exposed and unexposed parts is produced in the second layer,

a developer which dissolves the exposed parts of the image being added to the second layer so that a structured resist is obtained with a structure in which the unexposed parts form lands and the exposed parts form trenches arranged between the lands, and

the structure of the structured resist being transferred into the first layer of the absorber material.

The process according to the invention is distinguished by the use of a resist which comprises a film-forming polymer which contains silicon atoms, the proportion of silicon atoms in the film-forming polymer preferably being chosen to be as high as possible. In the oxygen plasma, the film-forming polymer or the silicon atoms contained therein is or are converted into silica. Silica is substantially inert to further attack by the oxygen plasma. During the plasma etching, very little or no structure loss therefore occurs, so that a structure defined in the resist by means of an electron beam can be transferred with high accuracy into the layer of the absorber material. It is therefore no longer necessary to provide a structure reserve in the design of the photomask, and structures having very small dimensions of less than 100 nm can therefore readily also be produced in the photomask. Furthermore, rounding of edges can be substantially suppressed, so that even complex structures which comprise, for example, right angles or edges can be exactly represented. As a further advantage, a considerably higher oxygen content of the plasma can be employed when transferring a structure produced from the resist into an absorber material, so that depletion of the etching plasma, which is also referred to as a loading effect, can be avoided.

When carrying out the process according to the invention, a transparent substrate is first provided. The substrate is transparent to the exposure radiation subsequently used for structuring a semiconductor substrate, and generally consists of quartz glass. A first layer of an absorber material is then deposited on the substrate. For the production of COG masks, for example, a chromium layer is deposited for this purpose. The deposition can be effected, for example, by sputtering. However, absorber material used may also be other materials, for example semitransparent materials or phase-shift materials. Examples of further materials are titanium and MoSi.

A layer of the resist described above and intended for electron beam lithography is then applied to the first layer. Customary methods may be used for this purpose, for example spin coating, spraying on or dip methods. In order to obtain a solid resist film, the solvent contained in the resist is then evaporated so that a second layer of the film-forming polymer contained in the resist is obtained. For this purpose, the substrate of the applied resist layer can, for example, be heated. The resist film is now written on with the aid of a focused electron beam so that an image which comprises the exposed and unexposed parts is produced in the second layer. By writing with an electron beam, a certain mask layout is imprinted into the second layer formed from the film-forming polymer. The polymer is cleaved into shorter fragments by means of the energy of the electron beam, so that a chemical differentiation between exposed and unexposed parts is effected. Customary mask writers can be used for writing on the resist film. A developer which dissolves the exposed parts of the image is now added to the second layer so that a structured resist is obtained in which the unexposed parts of the image form lands and the exposed parts of the image form trenches arranged between the lands. A suitable developer is an organic solvent which does not dissolve the film-forming polymer but in which the fragments formed from the film-forming polymer are soluble. Suitable solvents are, for example, butyl lactate, γ-butyrolactone, methyl ethyl ketone, isopropanol or methyl isobutyl ketone. The solvents can be used alone or in the form of a mixture of a plurality of solvents. For example, a 1:1 mixture of methyl ethyl ketone and isopropanol is suitable. Customary methods can be used for adding the developer, for example puddle methods or dip methods. Excess developer can then be removed. The structure can now be transferred into the first layer of the absorber material by removing the absorber material in the sections bared in the trenches, for example by etching by means of a suitable plasma. The plasma has a customary composition, as already used in the case of the processes customary to date for the production of COG masks. However, the plasma may have a higher oxygen content in order to suppress depletion effects. By means of the plasma, the silicon atoms contained in the film-forming polymer are converted into silica, which remains as a protective layer on those sections of the first layer of the absorber material which form the absorber structures in the prepared photomask.

The resist used in the process according to the invention comprises a film-forming polymer which comprises as high a proportion of silicon atoms as possible, and a solvent. All conventional solvents or mixtures thereof which are capable of taking up the film-forming silicon-containing polymer to give a clear, homogeneous and storage-stable solution and which ensure a good layer quality during coating of the transparent substrate can be used as solvents. For example, methoxypropyl acetate, cyclopentanone and cyclohexanone, γ-butyrolactone, ethyl lactate, diethylene glycol, dimethyl ether or a mixture of at least two of these solvents can be used as solvent of the resist. For the production of the resist, the film-forming silicon-containing polymer is dissolved in a suitable solvent. Suitable compositions of the resist are in the following ranges:

film-forming silicon-containing polymer: 1-50% by weight, preferably 2-10% by weight;

solvent: 50-99% by weight, preferably 88-97% by weight.

Additional further components/additives which advantageously influence the resist system with respect to dissolution, film formation properties, storage stability, radiation sensitivity and pot life effect can be added to the resist. In addition to the film-forming silicon-containing polymer and the solvent, the resist may contain, for example, sensitizers or solubilizers.

The structure of the film-forming polymer can be varied within wide limits, but a sufficiently high content of silicon atoms must always be ensured in order to guarantee sufficient stability of the structures produced on the resist to an etching plasma having a high oxygen content.

According to a first preferred embodiment, the film-forming polymer comprises, in addition to at least one further repeating unit, first repeating units which carry at least one silicon-containing side group.

The film-forming polymer can be prepared by free radical copolymerization of a silicon-containing comonomer and further comonomers using customary processes. For this purpose, the comonomers each comprise at least one carbon-carbon double bond capable of free radical polymerization, so that the polymer has a main chain formed from carbon atoms. The free radical polymerization can be carried out in solution or in a solvent-free system. Free radical initiators which may be used for the free radical polymerization are customary free radical initiators, for example benzoyl peroxide or azobisisobutyronitrile (AIBN). By means of the silicon-containing comonomer, silicon-containing groups are introduced into the film-forming polymer, the silicon-containing groups being arranged as side groups on the polymer main chain. The silicon-containing comonomer may have a wide structural variety, but it is preferable for the first comonomer to comprise no further functional groups apart from the polymerizable carbon-carbon double bond and the silicon-containing group. Examples of suitable comonomers are shown below: 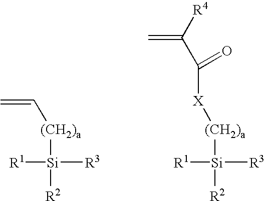
Here:
R¹, R² and R³ denote an alkyl group having 1 to 10 carbon atoms;
R⁴ denotes a hydrogen atom or an alkyl group having 1 to 10 carbon atoms;
X denotes oxygen or an NH group;
a denotes an integer from 1 to 10.

Trimethylallylsilane and derivatives of acrylic acid and methacrylic acid are particularly preferred as silicon-containing comonomers.

The first repeating unit derived from the silicon-containing comonomer is contained in the film-forming polymer preferably in an amount of from 10 to 90 mol %, particularly preferably from 50 to 90 mol %.

According to a preferred embodiment, the film-forming polymer described above contains, in addition to the silicon-containing first repeating units, second repeating units which are derived from inert comonomers, as further repeating units. Inert comonomers are understood as meaning comonomers which, apart from the polymerizable carbon-carbon double bond, contain no further functional groups which permit chemical modification of the film-forming polymer, for example by elimination of groups or by a subsequent linkage of groups by reaction with the film-forming polymer. In this case, the resist preferably contains no further components apart from the film-forming polymer and the solvent. The differentiation between exposed and unexposed sections of the resist is therefore effected by fragmentation of the polymer main chain.

Repeating units which are derived from alkyl esters of (meth)acrylic acid are preferably used as second repeating units. The alkyl chain of the esters preferably comprises 1 to 10 carbon atoms, it being possible for the alkyl chains to be straight or branched. Particularly preferably, the second repeating units are derived from methyl methacrylate.

In addition to the silicon-containing first repeating units and the optionally contained second repeating units derived from inert comonomers, the film-forming polymer may contain further repeating units which permit subsequent modification of the film-forming polymer. For this purpose, the film-forming polymer comprises, as further repeating units, third repeating units which contain at least one anchor group. An anchor group is understood as meaning a functional group which can be nucleophilically attacked by a nucleophilic group with formation of a covalent bond, so that groups can be subsequently introduced into the film-forming polymer.

For this purpose, an amplification agent which comprises a group which can coordinate to the anchor group is applied to the structured resist. The anchor groups contained in the film-forming polymer must have sufficient reactivity to be able to undergo a sufficient reaction with an amplification reagent within periods suitable for industrial application, by means of which reaction groups for increasing the etch resistance are introduced into the polymer. Anchor groups which have sufficient reactivity are, for example, isocyanates, epoxides, ketenes, oxiranes, urethanes or acid anhydrides. Carboxylic anhydride groups have proved to be particularly advantageous since they have, on the one hand, sufficient stability to permit uncomplicated preparation and processing of the film-forming polymer or of the resist and, on the other hand, a sufficiently high reactivity to undergo a reaction with an amplification agent within periods of interest for an industrial application. Third repeating units which are derived from an at least monounsaturated carboxylic anhydride are therefore particularly preferred. At least monounsaturated is understood as meaning that the carboxylic anhydride has at least one polymerizable carbon-carbon double bond. For example, cyclohexenedicarboxylic anhydride, itaconic anhydride, norbornenedicarboxylic anhydride and methacrylic anhydride are suitable as comonomers by means of which an anchor group can be introduced into the film-forming polymer. A particularly suitable at least monounsaturated carboxylic anhydride is maleic anhydride. Maleic anhydride can be readily introduced as a comonomer into the polymer by free radical polymerization during a preparation of the film-forming polymer. The third repeating units derived from maleic anhydride have sufficient reactivity for a reaction with an amplification agent in order to permit an industrial application. Furthermore, maleic anhydride can be economically obtained.

The group provided on the amplification agent must on the other hand have a certain nucleophilicity to be able to react with the anchor groups of the film-forming polymer. Suitable nucleophilic groups are, for example, hydroxyl groups, thiol groups or particularly preferably amino groups. In order to permit linkage of the amplification agent, the amplification agent is left on the structured resist for a certain time so that the amplification agent is bound to the film-forming polymer and an amplified structure is obtained. The time which is required for the reaction of the amplification agent with the anchor groups of the film-forming polymer can be controlled, for example, by the concentration in which the amplification agent is applied to the structured resist or by the temperature at which the reaction is carried out. The reaction with the amplification agent is continued until a certain modification of the film-forming polymer has been achieved. Excess amplification agent can be removed after the end of the reaction. In this way, the silicon content of the polymer can be subsequently increased by introducing additional silicon-containing groups into the film-forming polymer. Not only can the etch resistance of the structured resist be increased but also the width of the structures after development can be subsequently enlarged and in this way a structure reserve subsequently produced. In this embodiment of the process according to the invention, the polymer need not already contain silicon-containing groups in order to ensure sufficient etch resistance in the oxygen plasma, since the silicon-containing groups can be introduced subsequently into the polymer and sufficient etch resistance of the amplified structures can thus be achieved.

The amplified structure is then transferred, as described above, into the first layer of the absorber material. For this purpose, the bare absorber material in the trenches of the resist structure is etched away.

The amplification agent can be applied from the gas phase to the structured resist. Preferably, however, the amplification agent is applied as a solution to the structured resist. The film-forming polymer in the structured resist may be swollen by the solvent, with the result that the amplification agent can also penetrate into deeper parts of the resist structure in order to react there with the anchor groups of the film-forming polymer. Furthermore, excess amplification agent can easily be removed by centrifuging or washing.

The amplification agent can also be applied as a solution in the developer to the exposed resist. In this embodiment of the process, the development of the exposed resist and the amplification of the structured resist are effected simultaneously in one operation, with the result that the production of the amplified structure can be simplified and shortened.

In this embodiment of the process, the etch stability of the resist to an oxygen plasma can be subsequently increased. According to the invention, additional silicon-containing groups which are converted in the oxygen plasma into nonvolatile silica and form a protective layer on the absorber material are introduced into the polymer for this purpose. For this purpose, the amplification agent comprises a silicon-containing group.

Particularly preferably, the amplification agent comprises at least two reactive groups. In the amplification, further crosslinking of the polymer is effected by the amplification agent, with the result that the stability of the resist structure increases and dissolution of the amplified resist by a solvent is substantially suppressed.

The amplification agent is preferably a silicon compound provided with basic functions, in particular an aminosiloxane. Chain-like methylsiloxanes having terminal aminopropyl units and 2 to 51, preferably 2 to 12, silicon atoms per molecule have proved particularly useful. Such a chain-like dimethylsiloxane is shown below by means of its structural formula.

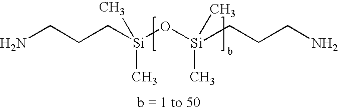

Further examples of amplification agents having amino-functional groups may be represented by the following general structural formulae. 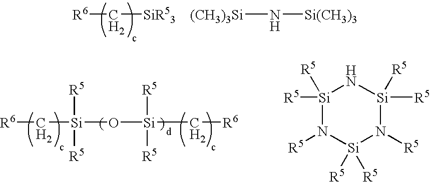
in which
c is an integer from 1 to 20,
d is an integer from 0 to 30,
R⁵ is H, alkyl or aryl, and
R⁶ is

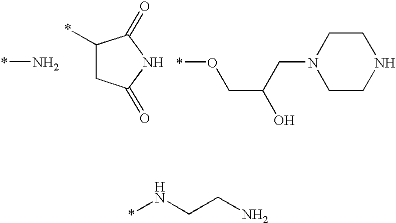

In this embodiment of the resist according to the invention, the film-forming polymer contains first repeating units, which contain silicon atoms, and third repeating units which comprise anchor groups. The polymer can optionally also comprise second repeating units which have no reactive groups, for example acrylates, methacrylate or repeating units derived from styrene. In such a resist, the differentiation of the resist film is likewise effected by fragmentation of the polymer main chain under the action of a focused electron beam. The development of the exposed resist film is then effected by means of a solvent in which the polymer fragments are more readily soluble than the film-forming polymer itself. In general, organic solvents are used, for example those mentioned further above.

Another mechanism for differentiation between exposed and unexposed parts is permitted if the film-forming polymer comprises, as further repeating units in addition to the first repeating units comprising at least one silicon-containing group, fourth repeating units which have an acid-labile group which is cleaved under the action of acids and liberates a group which results in an increase in the solubility of the polymer in aqueous alkaline developers.

In this embodiment of the process, the resist is in the form of a chemically amplified resist. In order to provide the acid for the cleavage of the acid-labile groups, a photo acid generator is additionally contained in the resist.

In such a resist, a differentiation between exposed and unexposed parts is achieved by the different polarity of the polymer. In the unexposed parts, the film-forming polymer remains in its original nonpolar state and is therefore insoluble in an alkaline aqueous developer. In the exposed parts, the acid-labile groups have been cleaved, with the result that polar groups are liberated. This ensures that the polymer is now readily soluble in alkaline aqueous developer solutions and the resist is therefore dissolved only in the exposed parts by the developer solution during the development.

In this embodiment of the process according to the invention, a layer of the resist is first produced, as explained above, on the first layer of the absorber material and is written on by means of a focused electron beam so that an image which comprises exposed and unexposed parts is produced in the second layer. By exposure to the electron beam, a strong acid is liberated from the photo acid generator. Thus, a latent image of the desired structure is first obtained. The exposed resist is then heated, generally at temperatures in the range from 80 to 150° C. The acid-labile groups are cleaved thereby under the influence of the acid and contrast is imparted to the resist film, i.e. the desired structure is chemically imprinted into the resist film.

The cleavage of the acid-labile radical with liberation of a polar group is shown below by way of example for two preferred repeating units. In the first example, the repeating unit comprises a tert-butyl ester group, from which a carboxyl group is liberated under the action of acid.

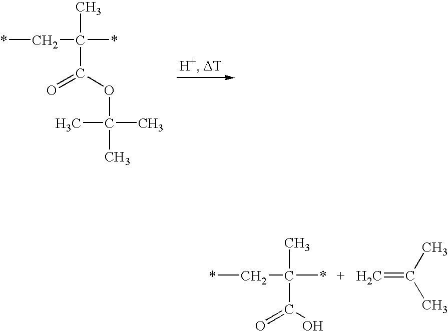

In the second example, the acid-labile group comprises a tert-butoxycarbonyloxy radical which is bonded to a phenolic hydroxyl group. Under the action of acid, an acidic hydroxyl group is therefore liberated as the polar group.

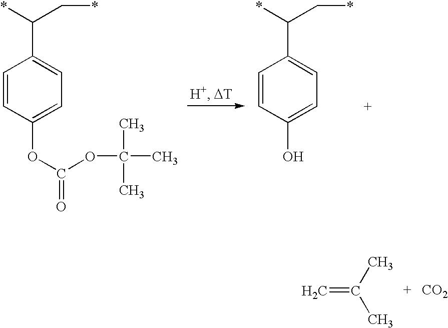

As a result of the chemical amplification, the resist has a high sensitivity to exposure to the electron beam, and for this reason the exposure times can be shortened. Consequently, pot life effects which are caused, for example, by diffusion of the liberated acid or by neutralization of the liberated acid by basic compounds introduced from the environment can be effectively suppressed.

The development of the exposed and contrasted resist film then follows with an aqueous alkaline developer, for example a 2.38% strength aqueous tetra-methylammonium hydroxide solution. Such developers can be obtained from commercial suppliers. In the exposed parts, the photoresist is dissolved by the developer and the absorber material arranged under the photoresist is bared. Transfer of the structure into the first layer of the absorber material is then effected again, as described above. For this purpose the absorber material is etched away in the bare sections, preferably using a plasma, for example an oxygen/chlorine plasma.

In this embodiment, the film-forming polymer may be composed only of first repeating units, which comprise a silicon-containing group, and fourth repeating units which have an acid-labile group. Such a film-forming polymer is suitable for the production of photomasks when a sufficiently high content of silicon atoms is contained in the film-forming polymer simply as a result of the first repeating unit. Owing to the catalytic effect of the liberated acid, only small exposure doses are required for exposure of the resist, i.e. short exposure times and hence fast throughputs are possible in mask production.

The first and fourth repeating units can be supplemented by second repeating units which are derived from inert comonomers, in particular acrylates and methacrylates.

If the resist is to be accessible to an amplification reaction, the film-forming polymer may additionally have third repeating units which have an anchor group.

For example, acrylates, methacrylates, maleic mono- and diesters, itaconic mono- and diesters, norbornene-carboxylic esters or norbornenedicarboxylic mono- and diesters are suitable as monomers by means of which an acid-labile group can be introduced into the polymer. Corresponding repeating units of the polymer are shown below. There, Y represents a radical which is cleavable by acid and after whose cleavage a polar group, for example a carboxyl or a hydroxyl group, is liberated. Examples of suitable acid-labile groups are: tert-alkyl ester, tert-butoxycarbonyloxy, tetrahydrofuranyl, tetrahydropyranyl, tert-butyl ether, lactone and acetal groups. tert-Butyl esters are particularly preferred. R⁷ represents a non-acid-labile radical, for example an alkyl group having 1 to 10 carbon atoms. Furthermore, e designates an integer from 1 to 10.

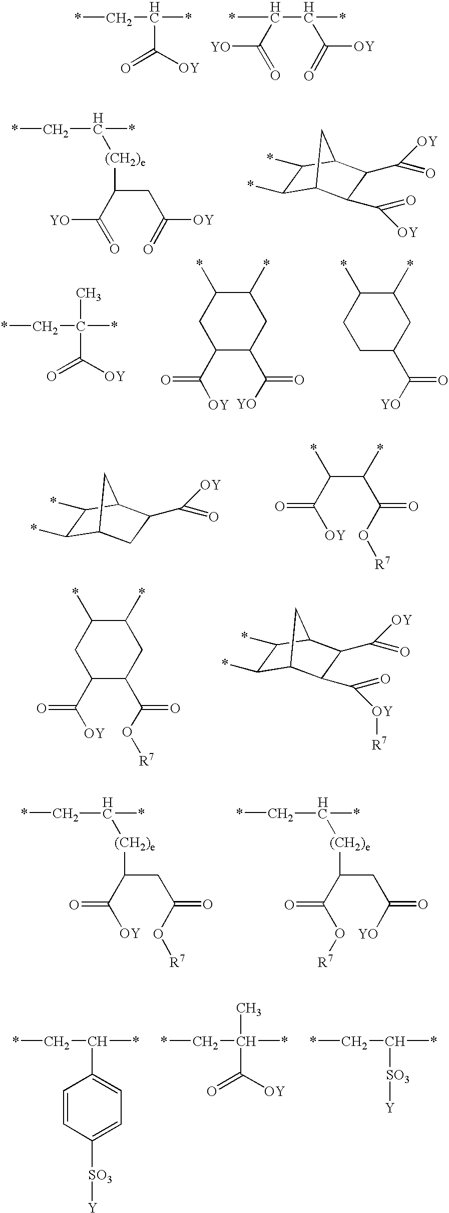

The photo acid generator additionally contained in the resist must have a sufficiently high sensitivity for the electron beam in order to be able to liberate an amount of acid required for rapid cleavage of the acid-labile groups. All compounds which liberate acid on exposure to radiation can be used as photo acid generators. Onium compounds as described, for example, in EP 0 955 562 A1 are advantageously used. The photo acid generator is contained in the resist in an amount of from 0.01 to 10% by weight, preferably from 0.1 to 1% by weight.

A further possibility for providing a high proportion of silicon atoms in the resist consists in providing a siloxane as the film-forming polymer. The siloxanes are advantageously substituted by carbon side chains, it also being possible for the carbon chains to comprise functional groups, for example acid-labile groups which are cleaved under the action of acid and liberate polar groups which result in an increase in the solubility of the polymer in polar alkaline developers. For example, the abovementioned groups may be used as acid-labile groups.

The preparation of such siloxanes can be effected by a plurality of methods, for example by grafting reactive monomers onto silicon-containing main chain polymers. It is possible to use only a single compound as a monomer or to copolymerize a plurality of different monomers. The polymer side chain formed from carbon atoms can be synthesized, for example, by free radical polymerization in the presence of silicon-containing polymers having aliphatic side groups. The linkage of the polymer part-chains composed of carbon atoms is effected by means of a chain transfer reaction. In this process, however, a broad distribution of the molecular weight of the reaction products has to be accepted. Targeted binding of the polymeric side chain to the silicon-containing main chain is also difficult to control.

Substantially more defined products are obtained by catalytic reaction of hydrosiloxane compounds or hydrosilsesquisoxane compounds with dienes in the presence of platinum/platinum complexes and subsequent free radical or anionic copolymerization of suitable unsaturated monomers. The polymers of the photoresist according to the invention can also be copolymerized with suitable unsaturated monomers by copolymerization of polymers which have alternating silicon and oxygen atoms in their main chain and in which an unsaturated group, such as a vinylphenylene group, is bonded as a side group to the main chain, the side chain formed from carbon atoms being produced.

In a further embodiment, the preparation of the polymers is effected by direct catalytic reaction of hydrosiloxane or hydrosilsesquioxane compounds with reactive unsaturated oligomers or polymers.

A preferred class of siloxanes which are suitable as a film-forming polymer in the resist according to the invention is formed by compounds of the formula I.

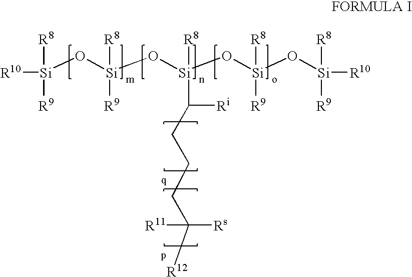

Polymer chains whose main chain is formed from carbon atoms are bonded to the siloxane chain composed of alternating silicon and oxygen atoms. The chain formed from carbon atoms has groups R^{s} which denote a hydrogen atom, an alkyl chain having 1 to 10 carbon atoms or preferably an acid-labile group. If the group R^{s} is in the form of an acid-labile group, differentiation of the dissolution properties between exposed and unexposed parts of the photoresist can be achieved by cleavage of said acid-labile group.

Specifically:

R⁸, R⁹ and R¹⁰, in each case independently of one another, are an alkyl radical having 1 to 10 carbon atoms, a cycloalkyl radical having 5 to 20 carbon atoms, an aryl radical having 6 to 20 carbon atoms, an aralkyl radical having 10 to 20 carbon atoms or a polar radical protected by an acid-labile group;

Rⁱ denotes a hydrogen atom, an initiator group or a polymer chain having an initiator group, the initiator group being formed from the polymerization initiator;

R¹¹ denotes hydrogen, halogen, pseudohalogen or an alkyl group having 1 to 10 carbon atoms;

R¹² denotes hydrogen or a polymer chain, the chain being formed from carbon atoms;

R^{s} denotes hydrogen, an alkyl group having 1 to 10 carbon atoms or an acid-labile group;

m and o denote 0 or an integer which is greater than or equal to 1, the sum of m and o being greater than 10;

n denotes an integer which is greater than or equal to 1;

q denotes 0 or an integer which is greater than or equal to 1;

p denotes an integer which is greater than or equal to 1;

it being possible for the repeating units characterized by the indices m, n and o to be arranged in any desired sequence. n is preferably less than 20 and q is preferably 0 or 1.

m and o are preferably chosen to be from 25 to 500, in particular from 50 to 500. p is preferably chosen to be from 1 to 500, particularly preferably from 5 to 50. The value of the indices is determined from the respective maximum of the molecular weight distribution of the polymer contained in the resist according to the invention.

The radicals R⁸, R⁹ and R¹⁰ bonded to the siloxane chain are preferably a methyl group, a cyclohexyl group or a phenyl group, it being possible for the radicals R⁸, R⁹ and R¹⁰ also to have different meanings with each occurrence on the siloxane chain. Polar groups which are protected by acid-labile groups may also be provided on the siloxane chain. An example of this is a tert-butoxycarbonylphenoxy group. Polymeric side chains whose chain is formed from carbon atoms are bonded to the siloxane main chain. This side chain may carry small nonpolar substituents R¹¹, such as methyl groups, trichloromethyl groups or nitrile groups. Furthermore, the polymeric side chain comprises groups R^{s} which may be in the form of acid-labile groups.

The side chain furthermore comprises a radical R¹² which continues the side chain formed from carbon atoms. Different monomers can be used here. Examples are methyl acrylates, methyl methacrylates or styrene derivatives. These monomers can be incorporated into the side chain either in the form of a block copolymerization or by copolymerization with the monomers containing the group R^{s}.

The linkage of the side chain to the siloxane main chain is effected by the reaction described above, for example by grafting or by copolymerization of the siloxane substituted by a polymerizable radical with the monomers which form the carbon side chain.

Depending on the reaction conditions, the group Rⁱ may be a hydrogen atom or an initiator group, by means of which, for example, a free radical polymerization was initiated, or a polymer chain having an initiator group. Examples of free radical initiators and initiator groups derived therefrom are shown in Table 1.

TABLE 1
Examples of free radical initiators and initiator
groups Rⁱ derived therefrom

| Free radical polymerization | Group Rⁱ remaining |
|---|---|
| initiator | on the polymer |
| 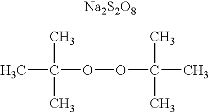 | 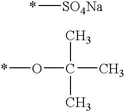 |
| 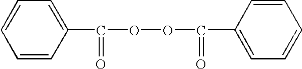 | 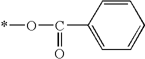 |
| 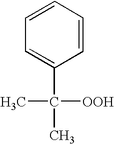 | 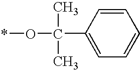 |
| 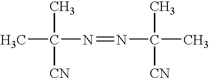 | 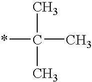 |
| 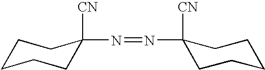 | 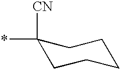 |

In addition to the free radical polymerization initiators shown, other diacyl peroxides or azo compounds may also be used.

Suitable cationic initiators are, for example, BF₃, TiCl₄, SnCl₄, AlCl₃ and other Lewis acids. In this case, Rⁱ is generally a hydrogen atom.

Examples of anionic initiators are shown in Table 2.

TABLE 2
Examples of anionic initiators and initiator groups Rⁱ
derived therefrom

| | | Group Rⁱ |
|---|---|---|
| | | remaining on |
| Initiator class | Initiator | the polymer |
| Alcoholates | 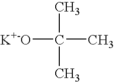 | 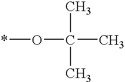 |
| Metal amides | Na⁺NH₂⁻ | —NH₂ |
| Metal alkyls | Li⁺⁻CH₂CH₂CH₃ | —CH₂CH₂CH₃ |
| | 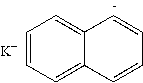 | 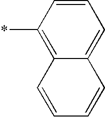 |

The proportion of silicon atoms in the resist can be further increased if the siloxane is in the form of a silsesquioxane. An example of suitable silsesquioxanes are compounds of the formula II. 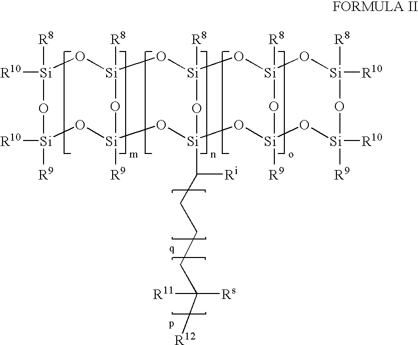
in which the radicals R⁸, R⁹, R¹⁰, R¹¹, R¹², Rⁱ and R^{s} and the indices m, n, o, p and q have the meaning stated in the case of formula I. The polymers derived from a silsesquioxane can be prepared by the same processes as described above.

In the siloxanes or silsesquioxanes, the polymeric carbon side chains may also have anchor groups which are available for amplification of the resist. Here for example, as also described above, carboxylic anhydride groups can be introduced. These are introduced into the side chain in the preparation of the polymeric side chain by copolymerization of monomers, such as maleic anhydride, itaconic anhydride, norbornenedicarboxylic anhydride, cyclohexanedicarboxylic anhydride or acrylic anhydride.

The invention is explained in more detail with reference to an attached figure. Identical objects are designated with identical reference numerals. Specifically, the figures show the following:

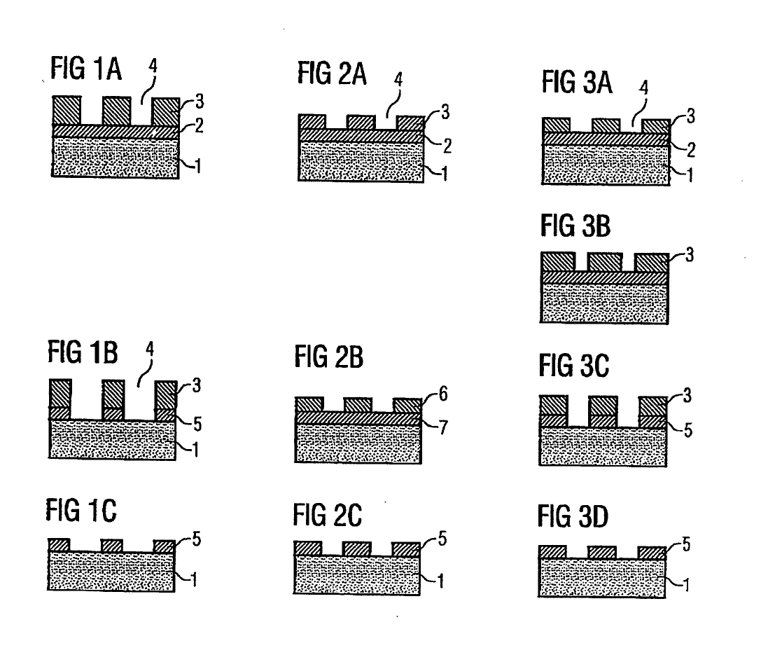

FIG. 1 shows a sequence of operations in the production of a COG mask according to the prior art;

FIG. 2 shows a sequence of operations in the process according to the invention;

FIG. 3 shows a sequence of operations in the process according to the invention, the resist structures being chemically amplified.

FIG. 1 shows the operations which are carried out in the production of a COG mask by processes known from the prior art. First, a layer 2 of chromium is applied to a transparent quartz substrate 1 by sputtering. A layer of polymethyl methacrylate is applied to the chromium layer 2 and then exposure is effected by means of a focused electron beam. During the development with an organic solvent, only those parts of the PMMA layer which have been exposed beforehand to the electron beam are selectively removed. An arrangement shown in FIG. 1a is therefore obtained after the development. A thin chromium layer 2 is arranged on the transparent quartz substrate 1, on which chromium layer lands 3 of PMMA are in turn arranged. Between the lands 3 are trenches 4 which correspond to the exposed sections of the resist and in which the chromium layer 2 is bare. If the bare chromium layer is now etched using an oxygen/chlorine plasma, not only the bare material in the trenches but also parts of the lands 3 are removed. Consequently, as shown in FIG. 1b, the width of the trenches 4 increases or the width of the lands 3 decreases. The width of the absorber structures 5 also corresponds to the width of the lands 3. Finally, the lands 3 of PMMA are removed, for example by ashing in the oxygen plasma or by dissolution using a suitable solvent. The photomask shown in cross section in FIG. 1c is obtained. Absorber structures 5 comprising chromium are arranged on the quartz substrate 1. The absorber structures 5 have a smaller width than the lands 3 originally produced in the resist (FIG. 1a). As a result of the etching, a structure loss therefore has to be accepted in the process according to the prior art.

In FIG. 2, the process steps for the production of the photomask using a silicon-containing resist are shown. First, as illustrated in FIG. 1, a thin layer of an absorber material (e.g. chromium) is applied to a quartz substrate 1. A layer of a silicon-containing resist is then applied to the chromium layer 2 and a structure is written into the resist layer by means of a focused electron beam. As a result of the exposure to the electron beam, modification of the film-forming polymer contained in the resist takes place. Either the polymer is fragmented into smaller fragments or, in combination with a subsequent heating step, polar groups are liberated on the polymer by cleavage of acid-labile groups. The exposed resist is then developed. Either an organic solvent in which the polymer fragments are soluble or an aqueous alkaline developer in which the polar form of the polymer is soluble is used for this purpose. A setup shown in FIG. 2a is obtained. A thin layer of chromium is arranged on a quartz substrate 1, on which layer of chromium lands 3 of the resist material are in turn arranged. Trenches 4 in which the chromium of the chromium layer 2 is bare are present in turn between the lands 3. The bare chromium in the trenches 4 is now once again etched away using a plasma. The silicon atoms contained in the film-forming polymer are converted into silica, which forms a protective layer 6 which prevents those sections 7 of the chromium layer which are present underneath from being attacked by the plasma. Since the sections 6 of silica are substantially inert to the plasma, there is no structure loss on removal of the bare sections of the chromium layer 2 which are present in the trenches 4, so that the width of the protective sections 6 substantially corresponds to the width of the lands 3 (FIG. 2b). Finally, the sections 6 are removed. This can be effected, for example, by a wet chemical method using customary, commercially available strippers. These strippers are generally strongly alkaline organic reagents. The chromium mask shown in cross section in FIG. 2c is obtained. Absorber structures 5 whose width substantially corresponds to the width of the resist lands 3 are arranged on a quartz substrate 1.

Any resulting structure loss can be compensated by chemically amplifying the structured resist. The steps implemented in this process variant are shown in FIG. 3. FIG. 3a corresponds to the state as shown in FIG. 2a. Here, however, the resist comprises a polymer which has anchor groups for linkage of an amplification agent. FIG. 3a shows a transparent quartz substrate 1 on which a thin chromium layer 3 is in turn arranged, on which chromium layer in turn are arranged lands 3, which however contain a polymer which comprises anchor groups. Since in this case silicon-containing groups are subsequently introduced into the polymer, a silicon-free polymer can also be used for the production of the lands 3. A solution of an amplification agent is now added to the resist structure shown in FIG. 3a. The amplification agent is bound to the anchor groups of the polymer, with the result that there is an increase in the volume of the lands 3. Consequently, as shown in FIG. 3b, the lands 3 increase in their width and height. The lands 3 thus now have a width which is greater in comparison with the state shown in FIG. 3a, and the trenches 4 accordingly have a reduced width. If the chromium layer is now etched with a plasma in the bare parts in the trenches 4, a loss of width of the lands 3 caused by a slight attack by the plasma on the material of the lands 3 can be compensated. The structure reserve obtained by the chemical amplification is removed by the plasma so that after the etching, as shown in FIG. 3c, the lands 3 once again have a width which is smaller in comparison with FIG. 3b. In contrast to the processes shown in FIG. 1a, the growth in the width of the lands 3 which is achieved by the amplification can, however, be controlled in such a way that the absorber structures 5 are obtained in the desired width. Finally, removal of the resist lands 3, for example using a suitable stripper, is once again effected, so that the mask shown in FIG. 3d is obtained. Absorber structures 5 which have a width similar to the resist lands 3 shown in FIG. 3a are shown on a quartz substrate 1.

What is claimed is:

1-10. (canceled)

11. A process for the production of photomasks for optical lithography comprising:
providing a transparent substrate;
depositing a first layer of an absorber material on the transparent substrate;
applying a layer of a resist for electron beam lithography to the first layer, the resist at least comprising:
a film-forming polymer comprising a first repeating unit that contains silicon atoms, and comprising at least one further repeating unit that comprises an acid-labile group that is cleaved under the action of acid and liberates a group that results in an increase in the solubility of the film-forming polymer in aqueous alkali developers and a solvent;
evaporating the solvent contained in the resist so as to give a second layer that contains the film-forming polymer;
recording on the second layer by means of a focused electron beam so that an image that comprises exposed and unexposed parts is produced in the second layer; and
adding a developer, which dissolves the exposed parts of the image, to the second layer so as to give a structured resist having a structure in which the unexposed parts form walls and the exposed parts form trenches arranged between the walls, and the structure of the structured resist is transferred into the first layer of the absorber material.

12. A process for the production of photomasks for optical lithography, comprising:
providing a transparent substrate;
depositing a first layer of an absorber material on the transparent substrate;
applying a layer of a resist for electron beam lithography to the first layer, the resist at least comprising:
a film-forming polymer that comprises a first repeating unit, which contains silicon atoms, and comprises a further repeating unit that contains anchor groups which can be treated with an amplification agent so that the amplification agent is bonded to the polymer and a solvent;
evaporating the solvent contained in the resist so as to give a second layer that contains the film-forming polymer;
recording on the second layer by means of a focused electron beam so that an image that comprises exposed and unexposed parts is produced in the second layer; and
adding a developer, which dissolves the exposed parts of the image, to the second layer so as to give a structured resist having a structure in which the unexposed parts form walls and the exposed parts form trenches arranged between the walls.

13. The process of claim 12, further including adding an amplification agent, which comprises a group that can coordinate to the anchor groups, to the structured resist, wherein the amplification agent is left for a certain time on the structured resist so that the amplification agent is bonded to the polymer, and wherein an amplified structure is obtained, optionally excess amplification agent is removed, and the amplified structure is transferred into the first layer of the absorber material.

14. The process of claim 12, wherein the repeating unit which contains anchor groups is an at least monounsaturated carboxylic anhydride.

15. The process of claim 12, wherein the amplification agent comprises silicon-containing groups.

16. The process of claim 11, wherein the film-forming polymer comprises a further repeating unit which is derived from a comonomer which is selected from the group comprising alkyl esters of (meth)acrylic acid.

17. The process of claim 12, wherein the film-forming polymer comprises a further repeating unit which is derived from a comonomer

18. A process for the production of photomasks for optical lithography, comprising:
providing a transparent substrate;
depositing a first layer of an absorber material on the transparent substrate;
applying a layer of a resist for electron beam lithography to the first layer, the resist at least comprising one film-forming polymer of siloxane and a solvent;
evaporating the solvent contained in the resist so as to give a second layer that contains the film-forming polymer;
recording on the second layer by means of a focused electron beam so that an image that comprises exposed and unexposed parts is produced in the second layer;
adding a developer, which dissolves the exposed parts of the image, to the second layer so as to give a structured resist having a structure in which the unexposed parts form walls and the exposed parts form trenches arranged between the walls, and the structure of the structured resist is transferred into the first layer of the absorber material.

19. The process of claim 18, wherein the siloxane is a silsesquioxane.

20. The process of claim 18, wherein groups are bonded to the siloxane which comprise an anchor group and/or an acid-labile group which is cleaved under the action of acid and liberates a group which results in an increase in the solubility of the siloxane in polar alkaline developers.

21. The process of claim 11, wherein the structure is transferred into the first layer by etching with a plasma.

22. The process of claim 12, wherein the structure is transferred into the first layer by etching with a plasma.

23. The process of claim 18, wherein the structure is transferred into the first layer by etching with a plasma.

24. A process for the production of photomasks for optical lithography comprising:
providing a transparent substrate;
depositing a first layer of an absorber material on the transparent substrate;
applying a layer of a resist for electron beam lithography to the first layer, wherein the resist at least comprises:
a film-forming polymer, comprising silicon atoms and a solvent;
evaporating the solvent contained in the resist to give a second layer that contains the film-forming polymer;
writing on the second layer by means of a focused electron beam so that an image which comprises exposed and unexposed parts is produced in the second layer;
adding a developer, which dissolves the exposed parts of the image, to the second layer so that a structured resist is obtained with a structure in which the unexposed parts form lands and the exposed parts form trenches arranged between the lands; and
transferring the structure of the structured resist into the first layer of the absorber material.

25. The process of claim 24, the film-forming polymer comprising, in addition to at least one further repeating unit, first repeating units which carry at least one silicon-containing side group.

26. The process of claim 24, the film-forming polymer comprising, as further repeating units, second repeating units which are derived from a comonomer which is selected from the group consisting of alkyl esters of (meth)acrylic acid.

27. The process of claim 24, the film-forming polymer comprising, as further repeating units, third repeating units which contain anchor groups, an amplification agent which comprises a group which can coordinate to the anchor groups being applied to the structured resist, the amplification agent being left on the structured resist for a certain time so that the amplification agent is bound to the polymer, and an amplified structure being obtained, any excess amplification agent being removed and the amplified structure being transferred into the first layer of the absorber material.

28. The process of claim 27, the further comonomer being an at least monounsaturated carboxylic anhydride.

29. The process of claim 24, the amplification agent comprising silicon-containing groups.

30. The process of claim 24, the film-forming polymer having, as further repeating units, fourth repeating units which comprise at least one acid-labile group which is cleaved under the action of acid and liberates a group which increases the solubility of the film-forming polymer in aqueous alkaline developers, and furthermore a photo acid generator being contained in the resist and, after production of the image by means of an electron beam, the resist being heated so that the acid-labile groups on the polymer are cleaved in the exposed parts, and the developer being an aqueous basic developer in which the polar polymer is soluble and the nonpolar polymer is insoluble.
